(19) United States
(12) Patent Application Publication
(10) Pub. No.: US 2003/0038380 A1
(43) Pub. Date: Feb. 27, 2003

(54) Apparatus for packing semiconductor die

(76) Inventors: Johnson C.H. Tzu, Taipei (TW); Hsu Po Chih, Hsinchu (TW)

Correspondence Address: Chun M. Ng, BLAKELY, SOKOLOFF, TAYLOR & ZAFMAN LLP, Seventh Floor, 12400 Wilshire Boulevard, Los Angeles, CA, 90025-1026, US

(21) Appl. No.: 09/940,736

(22) Filed: Aug. 27, 2001

(51) Int. Cl. H01L 23/495

(52) U.S. Cl. 257/784

(57) ABSTRACT

An apparatus is provided for packing semiconductor die. The apparatus will comprise the followings: Basically, a semiconductor die is sticked thereon a metal frame by a full tape which is an adhesive material, an uncovered housing is formed around the semiconductor die and around a part of the metal frame, wherein the metal frame having a metal wire connected the die below, a plurality of metal balls being connected under other parts of the metal frame. Also, some other related apparatus are provided.

### BACKGROUND OF THE INVENTION

1. Field of the Invention

The present invention relates to a semiconductor die package, and more specifically, by using lead frame and BGA method.

2. Description of the Prior Art

Developments in interconnect and packing is quite modest in comparison. The renewed interest in the high-density hybrid is driven by the requirement to handle large numbers of IC interconnections, the increasing clock rate of digital systems and the desire to pack greater functionality into smaller spaces. Therefore, the number of a package's leads becomes more and more. For example, a package known as Pin Grid Array (PGA) can accommodate over 200 leads. An important consideration in making small, high speed and high-density devices is providing packages capable of the spreading heat generated by the devices.

A further problem confronting the technology is the relentless need for more I/O per chip. A conventional lead frame package, such as SOP, PQFP, has a limitation to increase the number of the package's lead. In addition, the maximum speed of the lead frame package is less than 100 MHz, so that cannot meet the manufacturers' desire. One response to the requirement of providing packages for high speed and density devices has been developed. One such package type is plastic ball grid array (PBGA) that uses a bismaleimidetraizine (BT) as a substrate. The PBGA offers many advantages over conventional packages such as solder ball I/O and high speed. The PBGA package has high speed due to a short path for signal transformation. The solder balls are set on a package surface in a matrix array, which can provide more signal contacts. Although the PBGA has a shorter path for spreading heat than a conventional package, but a heater spreader or a heat slug can not be set on the backside of a die paddle due to the structure of the PBGA. Further, the substrate of the PBGA is made of BT so that the efficiency of spreading heat is poorer than the lead frame package.

As the mentioned above, the increasing clock rate of digital systems and the desire will pack greater functionality into smaller spaces. Therefore, the number of a package's leads becomes more and more. An important consideration in making small, high speed and high-density devices is providing packages capable of the spreading heat generated by the devices. A further problem confronting the technology is the relentless need for more I/O per chip. A conventional lead frame package, such as SOP, PQFP, has a limitation to increase the number of the package's lead. In addition, the maximum speed of the lead frame package cannot meet the manufacturers' desire.

One response to the requirement of providing packages for high speed and density devices has been developed. One such package type is ball grid array (BGA) that uses a bismaleimidetraizine (BT) as a substrate. For high I/O count IC chips, Ball grid array (BGA) packages have been used that can have more I/Os than QFPs. BGAs connect to PCBs using balls instead of pins or leads. Solder bumps or balls are attached to the lower surface of a substrate. These solder bumps or balls, in turn, provide the I/O connections of the BGA package. Such a configuration allows an increase in the number of I/O interconnects over conventional packages.

The BGA offers many advantages over conventional packages such as solder ball I/O and high speed. The BGA package has high speed due to a short path for signal transformation. The solder balls are set on a package surface in a matrix array that can provide more signal contacts. One type of the BGA package is called chip scale packages (CSP) that has a scale slightly larger than a chip. At present, several difficulties still limit the broad applications of a chip scale packaging technology in the field of package industry. One of the major difficulties is related to the issue of CSP production cost such as the manufacture equipment, the materials, the yields of each process. A low cost CSP package manufactured to produce highly reliable IC packages cannot be easily achieved.

As the mentioned above, with the rapid advances in wafer fabrication process technology, IC designers are always tempted to increase the chip level integration at an ever-faster pace. It has been the trend in integrated circuit (IC) technology to increase the density of semiconductor devices per unit area of silicon wafer. It follows then that the semiconductor devices, such as transistors and capacitors, must be made smaller and smaller. Further, the manufacturers of the devices are striving to reduce the size while simultaneously increasing their speed.

### SUMMARY OF THE INVENTION

In accordance with the present invention, a method is provided for packing semiconductor die that substantially increases the semiconductor speed and reduces the package size.

It is object for the present invention that the high frequency requirement is easily achieved.

It is another object for the present invention that the package cost can be exactly decreased.

It is other object for the present invention that the cycle time is shorter than before.

In the first feature of the embodiment, the method for packing a semiconductor die is described as the followings:

Firstly, a metal frame having a specific pattern is provided. Then, a material on the backside surface of a plurality of dice is laminated by using a adhesive material as a tape. The plurality of dice is located upon the metal frame. A metal wire is bonded to connect the plurality of dies below. Next, first molding the plurality of dice and parts of the metal frame to expose parts of the metal frame is achieved by a chemical compound. Then, the second individual molding the plurality of dice is carried out by the chemical compound. Next, a plurality of metal balls is placed to connect under other parts of the metal frame as an individual die package. Finally, the individual die package is punched to pack the semiconductor die.

In the second feature of the embodiment, the method for packing a semiconductor die is described as the followings:

Firstly, a metal frame having a specific pattern is provided. Then, a material on the backside surface of a plurality of dice is laminated by using an adhesive material as a tape. The plurality of dice is located upon the metal frame. A metal wire is bonded to connect the plurality of dice below. Next, first molding the plurality of dice and parts of the metal frame to expose parts of the metal frame is achieved by a chemical compound. Then, the second conformal molding the plurality of dice is carried out by the chemical compound. Next, a plurality of metal balls is placed to connect under other parts of the metal frame as an conformal die package. Finally, the conformal die package is singulated to pack the semiconductor die.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIGS. 1A to 1G are illustrative of various components in the cross-section with first embodiment of the present invention;

FIGS. 2A to 2G are illustrative of various components in the cross-section with second embodiment of the present invention;

FIGS. 3A to 3F are illustrative of various components in the cross-section with third embodiment of the present invention;

FIGS. 4A to 4F are illustrative of various components in the cross-section with fourth embodiment of the present invention;

FIGS. 5A to 5G are illustrative of various components in the cross-section with fifth embodiment of the present invention;

FIGS. 6A to 6G are illustrative of various components in the cross-section with sixth embodiment of the present invention;

FIGS. 7A to 7F are illustrative of various components in the cross-section with seventh embodiment of the present invention;

FIGS. 8A to 8F are schematic diagrams showing the cross-section of eighth embodiment of present invention;

FIGS. 9A to 9F are schematic diagrams showing the cross-section of ninth embodiment of present invention;

FIGS. 10A to 10E are schematic diagrams showing the cross-section of tenth embodiment of present invention;

FIG. 11A is illustrative in the cross-section with 11st embodiment of the present invention;

FIG. 11B is illustrative in the cross-section with 12nd embodiment of the present invention;

FIG. 12A is illustrative in the cross-section with 13rd embodiment of the present invention;

FIG. 12B is illustrative in the cross-section with 14th embodiment of the present invention;

FIG. 13A is illustrative in the cross-section with 15th embodiment of the present invention;

FIG. 13B is illustrative in the cross-section with 16th embodiment of the present invention;

FIG. 14A is illustrative in the cross-section with 17th embodiment of the present invention;

FIG. 14B is schematic diagram showing the cross-section of 18th embodiment of present invention;

FIG. 15A is schematic diagram showing the cross-section of 19th embodiment of present invention;

FIG. 15B is schematic diagram showing the cross-section of 20th embodiment of present invention;

FIG. 16A is illustrative in the cross-section with 21st embodiment of the present invention;

FIG. 16B is illustrative in the cross-section with 22nd embodiment of the present invention;

FIG. 17A is illustrative in the cross-section with 23rd embodiment of the present invention;

FIG. 17B is illustrative in the cross-section with 24th embodiment of the present invention;

FIG. 18A is illustrative in the cross-section with 25th embodiment of the present invention;

FIG. 18B is illustrative in the cross-section with 26th embodiment of the present invention;

FIG. 19A is illustrative in the cross-section with 27th embodiment of the present invention;

FIG. 19B is schematic diagram showing the cross-section of 28th embodiment of present invention;

FIG. 20A is schematic diagram showing the cross-section of 29th embodiment of present invention; and

FIG. 20B is schematic diagram showing the cross-section of 30th embodiment of present invention.

### DESCRIPTION OF THE PREFERRED EMBODIMENT

The following is a description of the present invention. The invention will firstly be described with reference to one exemplary structure. Some variations will then be described as well as advantages of the present invention. A preferred method of fabrication will then be discussed. An alternate, asymmetric embodiment will then be described along with the variations in the process flow to fabricate this embodiment.

Moreover, while the present invention is illustrated by a number of preferred embodiments directed to semiconductor package, it is not intended that these illustrations be a limitation on the scope or applicability of the present invention. Further, while the illustrative examples use lead frame, it should be recognized that the ceramic portions might be replaced with plastic portions. Thus, it is not intended that the semiconductor devices of the present invention be limited to the structures illustrated. These devices are included to demonstrate the utility and application of the present invention to presently preferred embodiments.

Therefore, the spirit of the proposed invention can be explained and understood by the following embodiments with corresponding figures. Especially, there is a method for packing a semiconductor wafer according to preferred embodiment of the present invention can be described the followings:

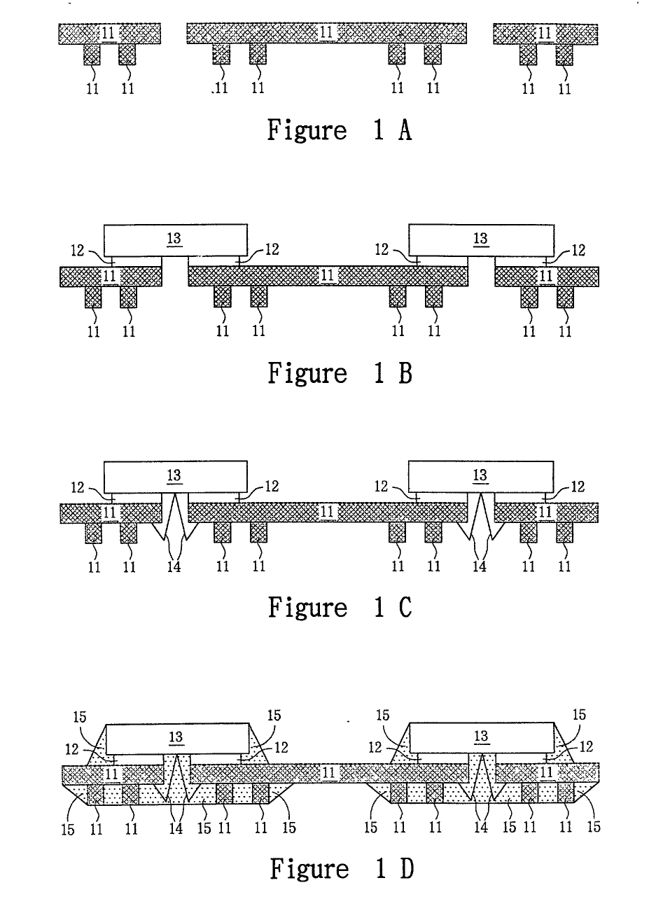

Firstly, the first embodiment of the present invention is showed as FIG. 1A. A metal frame 11, such as lead frame 11 is provided and the metal frame 11 is formed as a specific pattern. Especially the specific pattern is defined by the lithography including stamping process etc.

With reference to FIG. 1B, a material 12 is laminated on the backside surface of a plurality of dice 13. The material 12 is used by adhesive material as a tape. Still referring to FIG. 1B, the plurality of dice 13 is located upon the metal frame 11. Here, the plurality of dice 13 are formed from the semiconductor wafer or semiconductor chip.

Referring FIG. 1C, a metal wire 14 is bonded to connect the plurality of dice 13 below. Normally the metal wire 14 is formed by the gold wire.

Next, as FIG. 1D, first molding the plurality of dice 13 and parts of the metal frame 11 are achieved to expose parts of the metal frame 11 by a chemical compound such as plastic. Therefore, the first chemical compound housing 15 is formed around the plurality of dice 13. External pressure is introduced in the step to prevent the chemical compound from coating on the lower surface of the metal frame 11 portions.

Then, it is illustrated as FIG. 1E, second individual molding the plurality of dice 13 can be accomplished by the chemical compound, such as plastic or ceramic. The second chemical compound housing 16 is formed and covered on the above first chemical compound housing 15 and parts of the top surface of the metal frame 11.

As FIG. 1F shows, a plurality of metal balls 17 is placed to connect under other parts of the metal frame 11, which is the bottom portion of the metal frame 11, so that the individual die package 18 is obtained.

Finally, it is shown as FIG. 1G, the individual die package 18 is punched to become as a finished die package 19 in order to pack the semiconductor die. Especially, the punching line is set therebetween any two of the individual die package 18.

In the practical, the first embodiment of the invention is provided for the 64M SDRAM fabrication. In addition, the die specification is designed for the 0.18 μm wire width and the package size is about 9×12 mm.

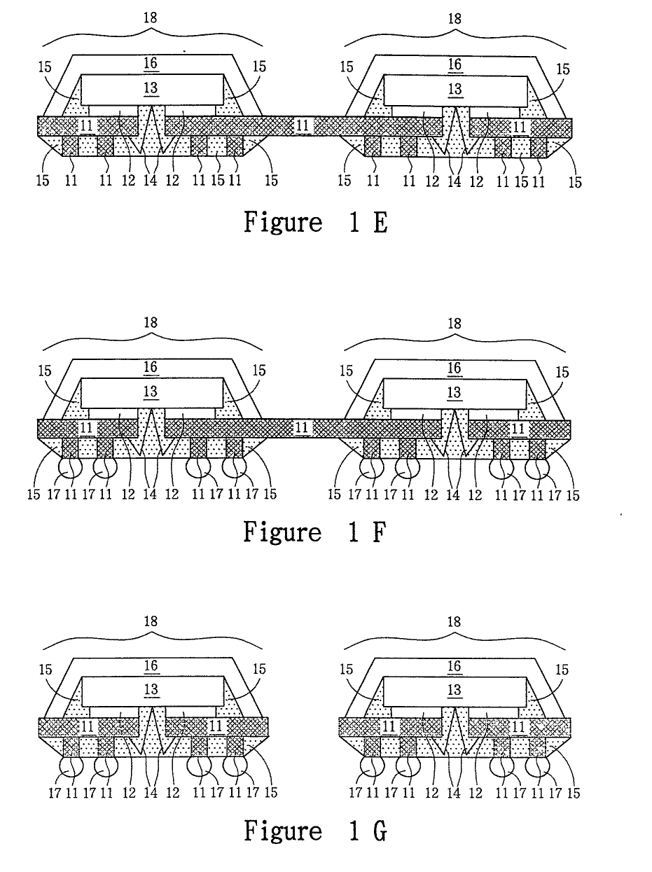

The second embodiment of the present invention is showed as FIG. 2A. Firstly, a metal frame 21, such as lead frame 21 is provided and the metal frame 21 is formed as a specific pattern. Especially the specific pattern is defined by the lithography including stamping process etc.

With reference to FIG. 2B, a material 22 is laminated on the backside surface of a plurality of dice 23. The material 22 is used by adhesive material as a tape. Still referring to FIG. 1B, the plurality of dice 23 is located upon the metal frame 21. Here, the plurality of dice 23 is formed from the semiconductor wafer or semiconductor chip.

Referring FIG. 2C, a metal wire 24 is bonded to connect the plurality of dice 23 below. Normally the metal wire 24 is formed by the gold wire.

Next, as FIG. 2D, first molding the plurality of dies 23 and parts of the metal frame 21 are achieved to expose parts of the metal frame 21 by a chemical compound such as plastic. Therefore, the first chemical compound housing 25 is formed around the plurality of dice 23. External pressure is introduced in the step to prevent the chemical compound from coating on the lower surface of the metal frame 21 portions.

Then, it is illustrated as FIG. 2E, second conformal molding the plurality of dice 23 can be accomplished by the chemical compound, such as plastic, ceramic or glass. The second chemical compound housing 25 is formed and covered on the above first chemical compound housing 25 and parts of the top surface of the metal frame 21.

As FIG. 2F shows, a plurality of metal balls 27 is placed to connect under other parts of the metal frame 11, which is the bottom portion of the metal frame 11, so that the conformal die package 28 is obtained.

Finally, it is shown as FIG. 2G, the conformal die package 28 is singulated to become as a finished die package 29 in order to pack the semiconductor die. Especially, the punching line is set therebetween any two of the conformal die package 28.

In the practical, using the lead frame and BGA, the second embodiment of the invention is provided for the 64M SDRAM fabrication. Especially the die specification is designed for the 0.18 urn wire width and the package size is about 9×12 mm.

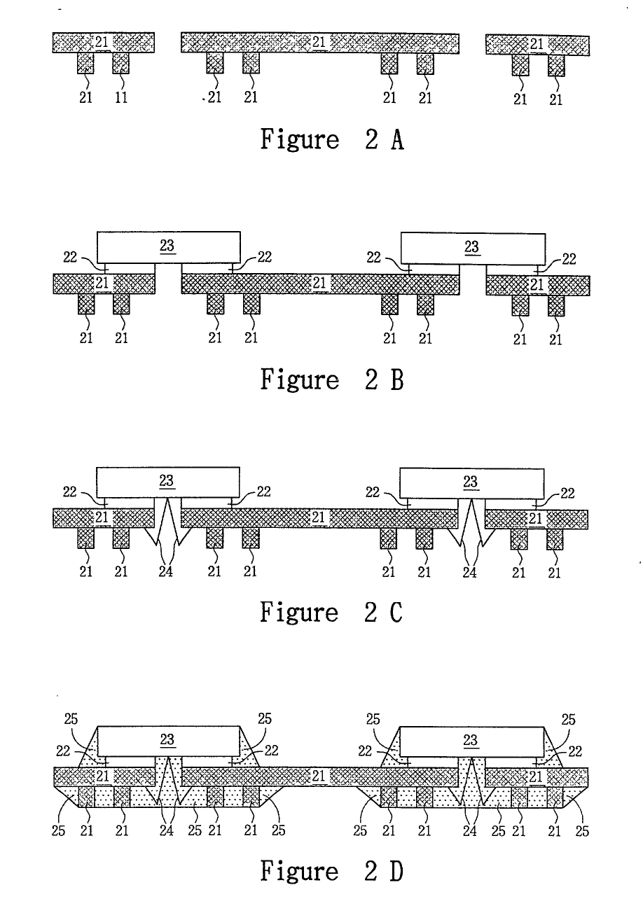

Firstly, the third embodiment of the present invention is showed as FIG. 3A. A metal frame 31, such as lead frame 31 is provided and the metal frame 31 is formed as a specific pattern. Especially the specific pattern is defined by the lithography including stamping process etc.

With reference to FIG. 3B, a material 32 is laminated on the backside surface of a plurality of dice 33. The material 32 is used by adhesive material as a tape. Still referring to FIG. 3B, the plurality of dice 33 is located upon the metal frame 31. Here, the plurality of dice 13 are formed from the semiconductor wafer or semiconductor chip.

Referring FIG. 3C, a metal wire 34 is bonded to connect the plurality of dice 33 below. Normally the metal wire 34 is formed by the gold wire.

Next, as FIG. 3D, first molding the plurality of dice 33 and parts of the metal frame 31 are achieved to expose parts of the metal frame 31 by a chemical compound such as plastic. Therefore, the first chemical compound housing 35 is formed around the plurality of dice 33. External pressure is introduced in the step to prevent the chemical compound from coating on the lower surface of the metal frame 31 portions.

Then, it is illustrated as FIG. 3E, second individual molding the plurality of dice 33 can be accomplished by the chemical compound, such as plastic or ceramic. The second chemical compound housing 36 is formed and covered on the above first chemical compound housing 35 and parts of the top surface of the metal frame 31, so that the individual die package 38 is obtained.

Finally, it is shown as FIG. 3F, the individual die package 38 is punched to become as a finished die package 39 in order to pack the semiconductor die.

In the practical, the third embodiment of the invention is provided for the 64M SDRAM fabrication. In addition, the die specification is designed for the 0.18 μm wire width and the package size is about 9×12 mm.

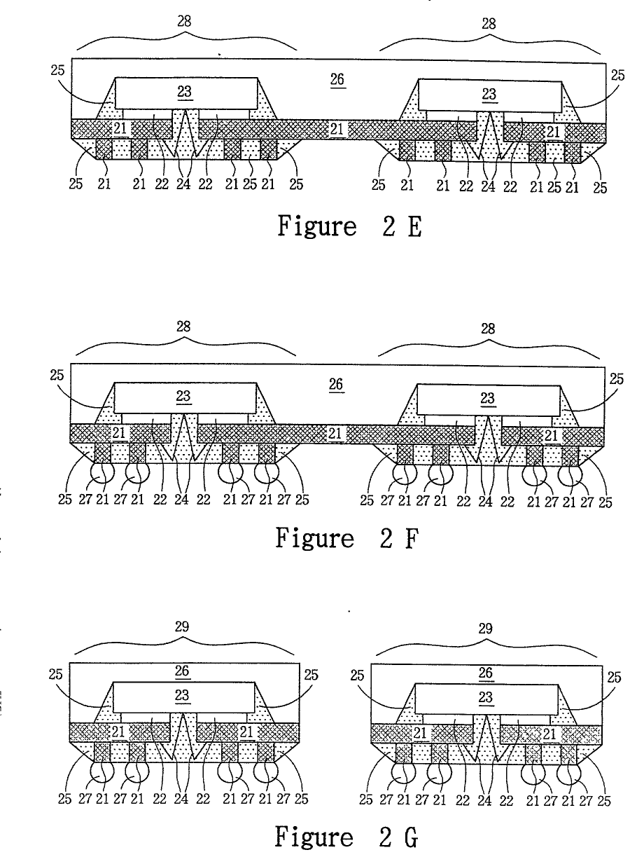

The fourth embodiment of the present invention is showed as FIG. 4A. Firstly, a metal frame 41, such as lead frame 41 is provided and the metal frame 41 is formed as a specific pattern. Especially the specific pattern is defined by the lithography including stamping process etc.

With reference to FIG. 4B, a material 42 is laminated on the backside surface of a plurality of dice 43. The material 42 is used by adhesive material as a tape. Still referring to FIG. 4B, the plurality of dice 43 is located upon the metal frame 41. Here, the plurality of dice 43 is formed from the semiconductor wafer or semiconductor chip.

Referring FIG. 4C, a metal wire 44 is bonded to connect the plurality of dice 43 below. Normally the metal wire 44 is formed by the gold wire.

Next, as FIG. 4D, first molding the plurality of dice 43 and parts of the metal frame 41 are achieved to expose parts of the metal frame 41 by a chemical compound such as plastic. Therefore, the first chemical compound housing 45 is formed around the plurality of dice 43. External pressure is introduced in the step to prevent the chemical compound from coating on the lower surface of the metal frame 41 portions.

Then, it is illustrated as FIG. 4E, second conformal molding the plurality of dice 43 can be accomplished by the chemical compound, such as plastic or ceramic. The second chemical compound housing 46 is formed and covered on the above first chemical compound housing 45 and parts of the top surface of the metal frame 41 so that the conformal die package 48 is obtained.

Finally, it is shown as FIG. 4F, the conformal die package 48 is singulated to become as a finished die package 49 in order to pack the semiconductor die.

In the practical, using the lead frame and BGA, the fourth embodiment of the invention is provided for the 64M SDRAM fabrication. Especially the die specification is designed for the 0.18 μm wire width and the package size is about 9×12 mm.

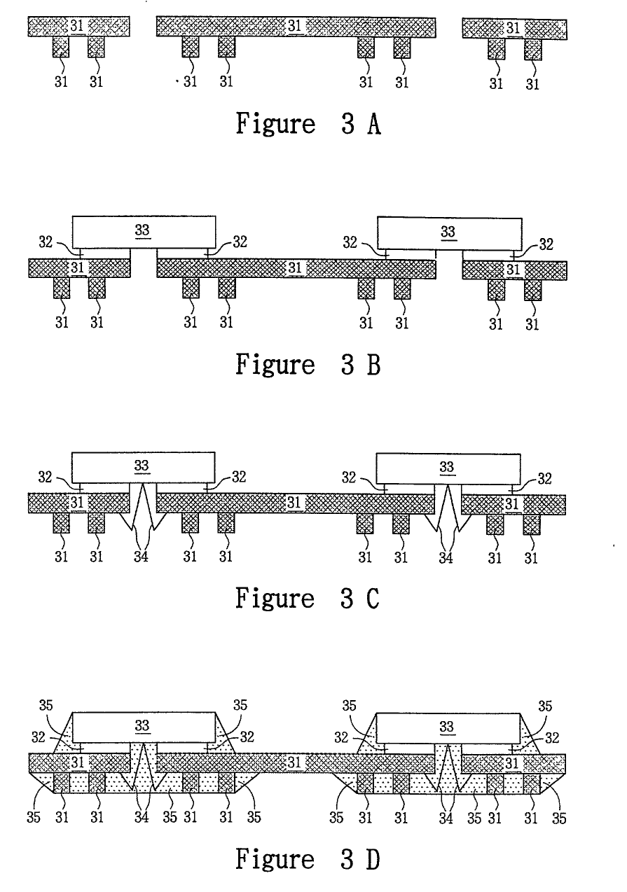

Firstly, the fifth embodiment of the present invention is showed as FIG. 5A. A metal frame 51, such as lead frame 51 is provided and the metal frame 51 is formed as a specific pattern. Especially the specific pattern is defined by the lithography including stamping process etc.

With reference to FIG. 5B, a material 52 is laminated on the backside surface of a plurality of dice 53. The material 52 is used by adhesive material as a tape. Still referring to FIG. 5B, the plurality of dice 53 is located upon the metal frame 51. Here, the plurality of dice 53 are formed from the semiconductor wafer or semiconductor chip.

Referring FIG. 5C, a metal wire 54 is bonded to connect the plurality of dice 53 below. Normally the metal wire 54 is formed by the gold wire.

Next, as FIG. 5D, first molding around a first side of the plurality of dice 53 as a first housing 55 and parts of the metal frame is achieved to expose another parts of the metal frame 51 by a chemical compound such as plastic. Especially a top surface of the plurality of dice 53 is exposed. External pressure is introduced in the step to prevent the chemical compound from coating on the lower surface of the metal frame 51 portions.

Then, as FIG. 5E, second individual molding around a second side of the first housing 55 is carried out as a second housing 56 by the chemical compound. Especially the top surface of the plurality of dice 53 is exposed, so that the cooling effect is better than before.

As FIG. 5F shows, a plurality of metal balls 57 is placed to connect under other parts of the metal frame 51, which is the bottom portion of the metal frame 51 so that the individual die package 58 is obtained.

Finally, it is shown as FIG. 5G, the individual die package is punched to become as a finished die package 59 in order to pack the semiconductor die. Especially, the punching line is set therebetween any two of the individual die package 58.

In the practical, the fifth embodiment of the invention is provided for the 64M SDRAM fabrication. In addition, the die specification is designed for the 0.18 μm wire width and the package size is about 9×12 mm.

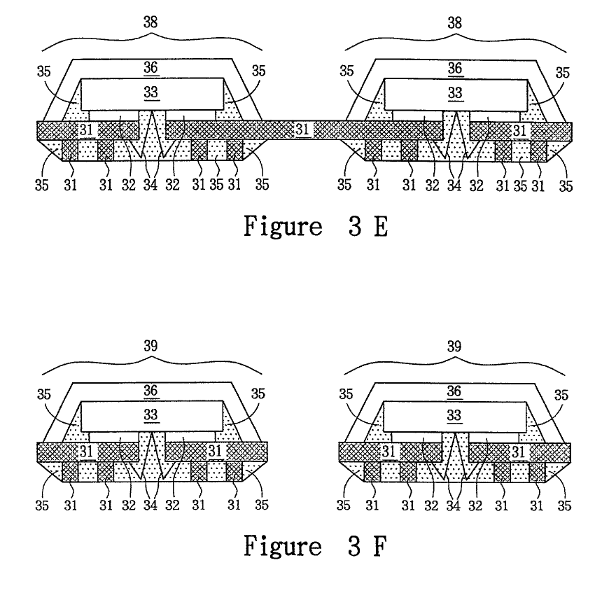

The sixth embodiment of the present invention is showed as FIG. 6A. Firstly, a metal frame 61, such as lead frame 61 is provided and the metal frame 61 is formed as a specific pattern. Especially the specific pattern is defined by the lithography including stamping process etc.

With reference to FIG. 6B, a material 62 is laminated on the backside surface of a plurality of dice 63. The material 62 is used by adhesive material as a tape. Still referring to FIG. 6B, the plurality of dies 63 is located upon the metal frame 61. Here, the plurality of dice 63 is formed from the semiconductor wafer or semiconductor chip.

Referring FIG. 6C, a metal wire 64 is bonded to connect the plurality of dice 63 below. Normally the metal wire 64 is formed by the gold wire.

Next, as FIG. 6D, first molding around a first side of the plurality of dice 63 as a first housing 65 and parts of the metal frame is achieved to expose another parts of the metal frame 61 by a chemical compound such as plastic. Especially a top surface of the plurality of dice 63 is exposed. External pressure is introduced in the step to prevent the chemical compound from coating on the lower surface of the metal frame 61 portions.

Then, as FIG. 6E, second conformable molding around a second side of the first housing 65 is carried out as a second housing 66 by the chemical compound. Especially the top surface of the plurality of dice 63 is exposed, so that the cooling effect is better than before.

As FIG. 6F shows, a plurality of metal balls 67 is placed to connect under other parts of the metal frame 61, which is the bottom portion of the metal frame 61 so that the conformal die package 68 is obtained.

Finally, it is shown as FIG. 6G, the conformal die package 68 is singulated to become as a finished die package 69 in order to pack the semiconductor die.

In the practical, using the lead frame and BGA, the sixth embodiment of the invention is provided for the 64M SDRAM fabrication. Especially the die specification is designed for the 0.18 μm wire width and the package size is about 9×12 mm.

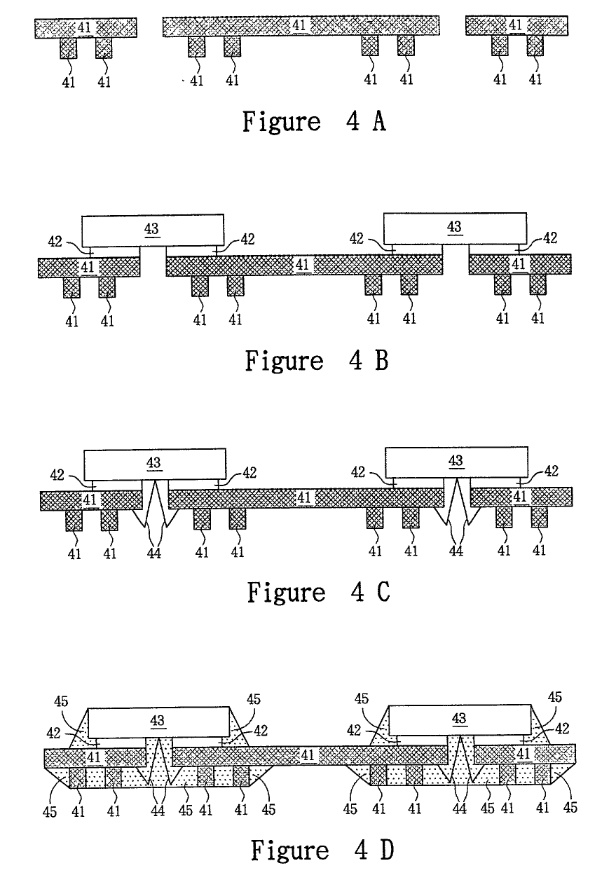

Firstly, the seventh embodiment of the present invention is showed as FIG. 7A. A metal frame 71, such as lead frame 71 is provided and the metal frame 71 is formed as a specific pattern. Especially the specific pattern is defined by the lithography including stamping process etc.

With reference to FIG. 7B, a material 72 is laminated on the backside surface of a plurality of dice 73. The material 72 is used by adhesive material as a tape. Still referring to FIG. 7B, the plurality of dice 73 is located upon the metal frame 71. Here, the plurality of dice 73 are formed from the semiconductor wafer or semiconductor chip.

Referring FIG. 7C, a metal wire 74 is bonded to connect the plurality of dice 73 below. Normally the metal wire 74 is formed by the gold wire.

Next, as FIG. 7D, first molding around a first side of the plurality of dice 73 as a first housing 75 and parts of the metal frame is achieved to expose another parts of the metal frame 71 by a chemical compound such as plastic. Especially a top surface of the plurality of dice 73 is exposed. External pressure is introduced in the step to prevent the chemical compound from coating on the lower surface of the metal frame 71 portions.

Then, as FIG. 7E, second individual molding around a second side of the first housing 75 is carried out as a second housing 76 by the chemical compound. Especially the top surface of the plurality of dice 73 is exposed as the individual die package 77, so that the cooling effect is better than before.

Finally, it is shown as FIG. 7F, the individual die package 77 is punched to become as a finished die package 78 in order to pack the semiconductor die.

In the practical, the seveth embodiment of the invention is provided for the 64M SDRAM fabrication. In addition, the die specification is designed for the 0.18 μm wire width and the package size is about 9×12 mm.

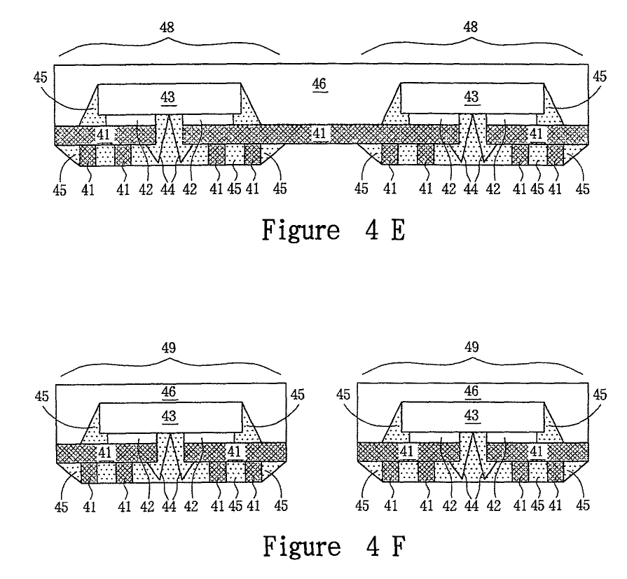

The eighth embodiment of the present invention is showed as FIG. 8A. Firstly, a metal frame 81, such as lead frame 81 is provided and the metal frame 81 is formed as a specific pattern. Especially the specific pattern is defined by the lithography including stamping process etc.

With reference to FIG. 8B, a material 82 is laminated on the backside surface of a plurality of dice 83. The material 82 is used by adhesive material as a tape. Still referring to FIG. 8B, the plurality of dice 83 is located upon the metal frame 81. Here, the plurality of dies 83 is formed from the semiconductor wafer or semiconductor chip.

Referring FIG. 8C, a metal wire 84 is bonded to connect the plurality of dice 83 below. Normally the metal wire 84 is formed by the gold wire.

Next, as FIG. 8D, first molding around a first side of the plurality of dice 83 as a first housing 85 and parts of the metal frame is achieved to expose another parts of the metal frame 81 by a chemical compound such as plastic. Especially a top surface of the plurality of dice 83 is exposed. External pressure is introduced in the step to prevent the chemical compound from coating on the lower surface of the metal frame 81 portions.

Then, as FIG. 8E, second conformal molding around a second side of the first housing 85 is carried out as a second housing 86 by the chemical compound. Especially the top surface of the plurality of dice 83 is exposed as the conformal die package 87, so that the cooling effect is better than before.

Finally, it is shown as FIG. 8F, the conformal die package 87 is singulated to become as a finished die package 88 in order to pack the semiconductor die.

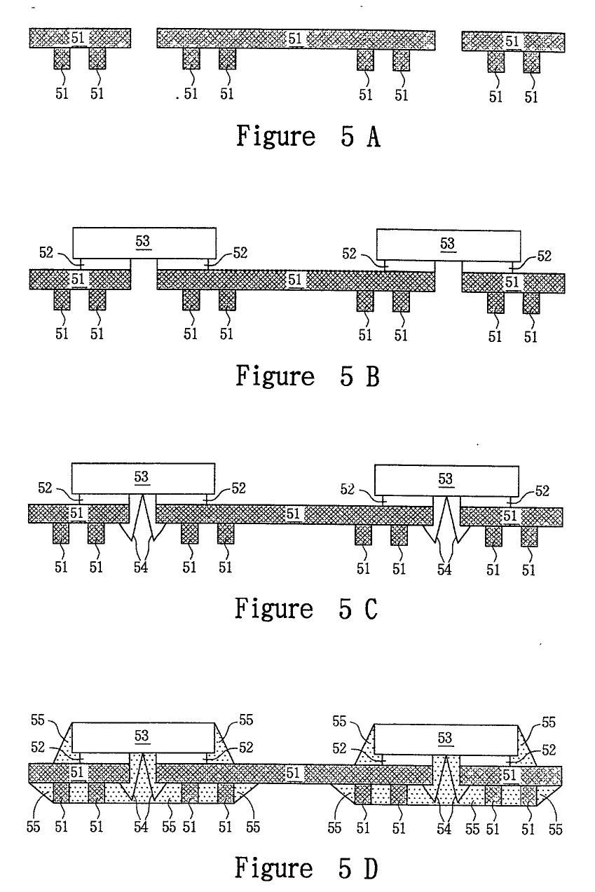

Next, the ninth embodiment of the present invention is showed as FIG. 9A. A metal frame 91, such as lead frame 91 is provided and the metal frame 91 is formed as a specific pattern. Especially the specific pattern is defined by the lithography including stamping process etc.

With reference to FIG. 9B, a material 92 is laminated on the backside surface of a die 93. The material 92 is used by adhesive material as a tape.

Referring to FIG. 9C, the die 93 is located upon the metal frame 91. Here, the plurality of dice 13 are formed from the semiconductor wafer or semiconductor chip.

Referring FIG. 9D, a metal wire 94 is bonded to connect the die 93 below. Normally the metal wire 94 is formed by the gold wire.

Next, as FIG. 9E, molding parts of the metal frame 91 are achieved to expose parts of the metal frame 91 by a chemical compound such as plastic. Here, External pressure is introduced in the step to prevent the chemical compound from coating on the lower surface of the metal frame 91 portions.

Finally, as FIG. 9F shows, a plurality of metal balls 96 is placed to connect under other parts of the metal frame 91, which is the bottom portion of the metal frame 91, so that the individual die package 98 is obtained.

In the practical, the tenth embodiment of the invention is provided for the 64M SDRAM fabrication. In addition, the die specification is designed for the 0.18 μm wire width and the package size is about 9×12 mm.

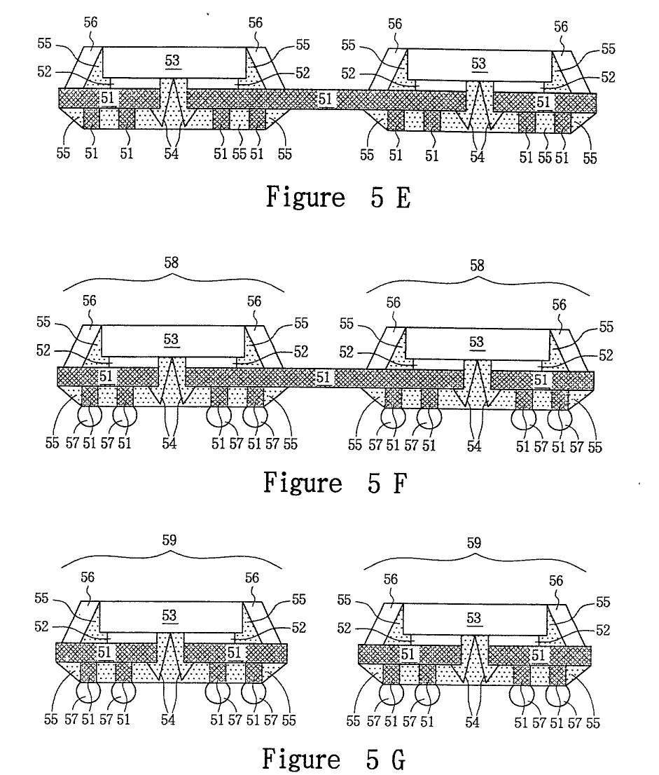

Consequentially, the tenth embodiment of the present invention is showed as FIG. 10A. A metal frame 101, such as lead frame 101 is provided and the metal frame 101 is formed as a specific pattern. Especially the specific pattern is defined by the lithography including stamping process etc.

With reference to FIG. 10B, a material 92 is laminated on the backside surface of a die 93. The material 102 is used by adhesive material as a tape.

Referring to FIG. 10C, the die 103 is located upon the metal frame 101. Here, the plurality of dice 13 are formed from the semiconductor wafer or semiconductor chip.

Referring FIG. 10D, a metal wire 104 is bonded to connect the die 103 below. Normally the metal wire 104 is formed by the gold wire.

Finally, as FIG. 10E, molding parts of the metal frame 101 are achieved to expose parts of the metal frame 101 by a chemical compound such as plastic (As bottom housing). Here, external pressure is introduced in the step to prevent the chemical compound from coating on the lower surface of the metal frame 101 portions.

In the practical, using the lead frame and BGA, the eighth embodiment of the invention is provided for the 64M SDRAM fabrication. Especially the die specification is designed for the 0.18 μm wire width and the package size is about 9×12 mm.

According to the above description, some of the related different package dies can be producted as the followings.

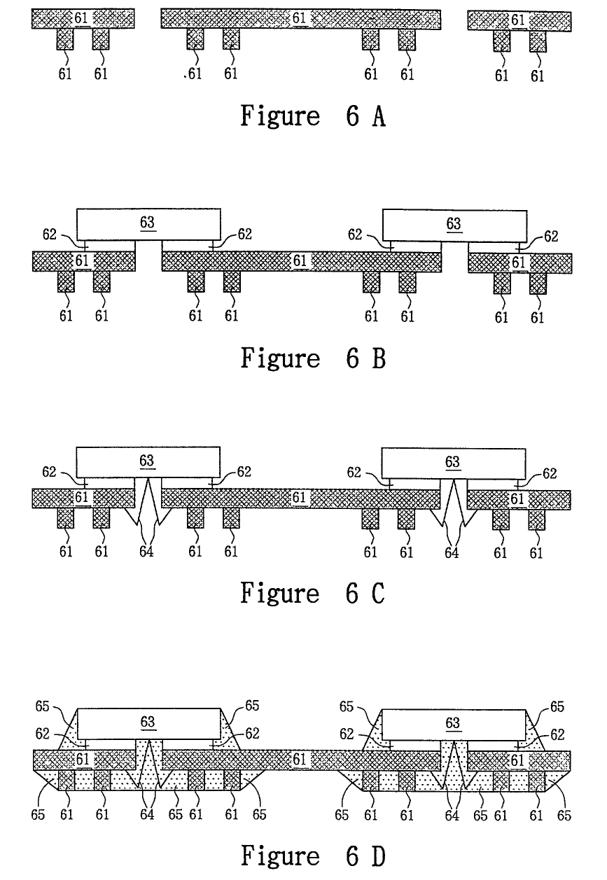

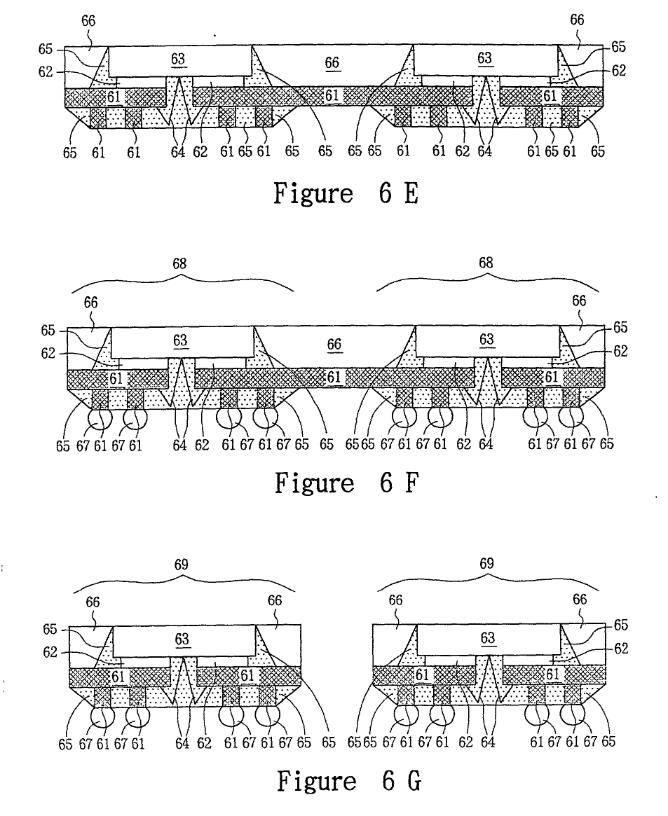

With reference FIG. 11A, the metal frame 110, such as lead frame 110 is provided and the metal frame 110 is formed as a specific pattern. Especially the specific pattern is defined by the lithography including stamping process etc. A full tape 111 such as adhesive material is laminated on the backside surface of a die 112 by the full tape 111. The die 112 is located upon the metal frame 110. Here, the plurality of dice 112 are formed from the semiconductor wafer or semiconductor chip. A metal wire 114 is bonded to connect the die 112 below and normally the metal wire 114 is formed by the gold wire. Then, molding parts of the metal frame 110 are achieved to expose parts of the metal frame 110 by a chemical compound 113 such as plastic. Especially a top surface of the plurality of dice 112 is exposed. Finally, A plurality of metal balls 115 are placed to connect under other parts of the metal frame 110, which is the bottom portion of the metal frame 110. Here, external pressure is introduced in the step to prevent the chemical compound from coating on the lower surface of the metal frame 110 portions.

With reference FIG. 11B, the metal frame 120, such as lead frame 120 is provided and the metal frame 120 is formed as a specific pattern. Especially the specific pattern is defined by the lithography including stamping process etc. A full tape 121 such as adhesive material is laminated on the backside surface of a die 122. The die 122 is located upon the metal frame 120 by the full tape 121. Here, the plurality of dice 122 are formed from the semiconductor wafer or semiconductor chip. A metal wire 124 is bonded to connect the die 122 below and normally the metal wire 124 is formed by the gold wire. Then, molding parts of the metal frame 120 are achieved to expose parts of the metal frame 120 by a chemical compound 123 such as plastic. Especially the top surface of the plurality of dice 122 is covered by the above chemical compound. Finally, a plurality of metal balls 125 are placed to connect under other parts of the metal frame 120, which is the bottom portion of the metal frame 120. Here, external pressure is introduced in the step to prevent the chemical compound from coating on the lower surface of the metal frame 120 portions.

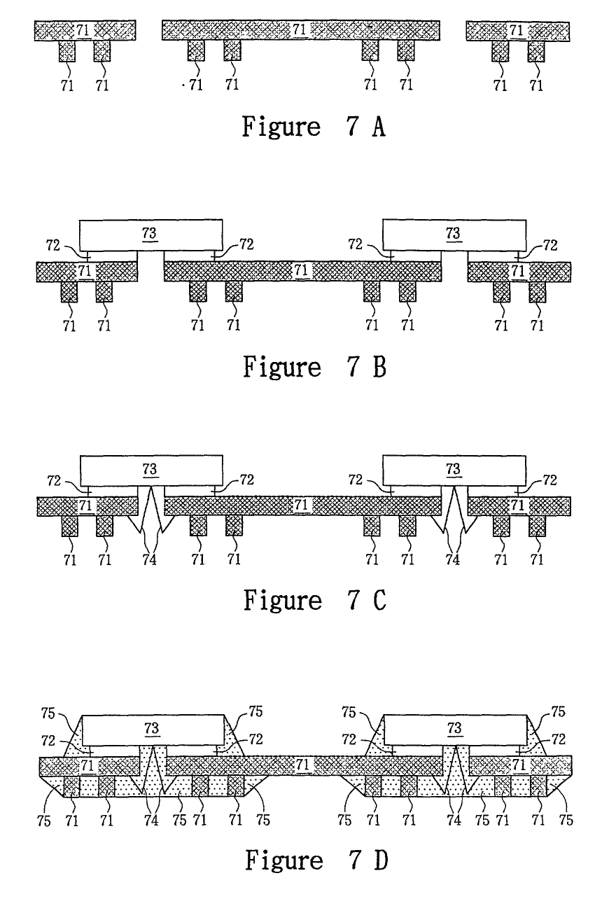

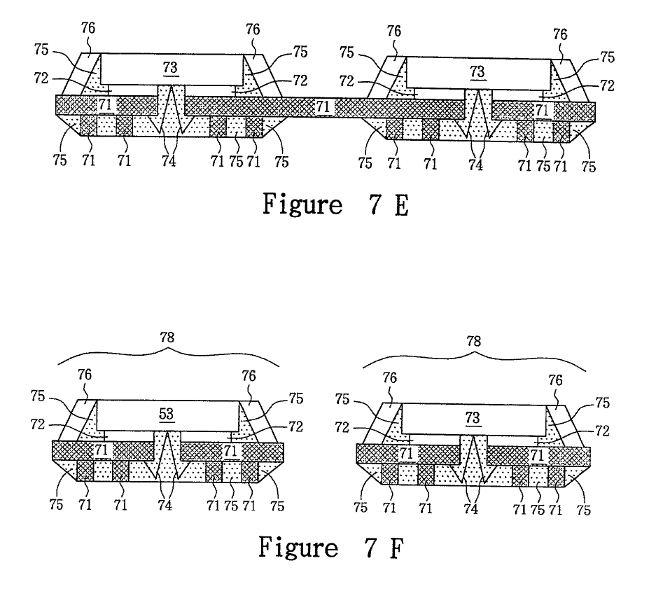

With reference FIG. 12A, the metal frame 210, such as lead frame 210 is provided and the metal frame 210 is formed as a specific pattern. Especially the specific pattern is defined by the lithography including stamping process etc. A full tape 211 such as adhesive material is laminated on the backside surface of a die 212. The die 212 is located upon the metal frame 210 by the full tape 211. Here, the plurality of dice 212 are formed from the semiconductor wafer or semiconductor chip. A metal wire 214 is bonded to connect the die 212 below and normally the metal wire 214 is formed by the gold wire. Finally, molding parts of the metal frame 210 are achieved to expose parts of the metal frame 210 by a chemical compound 213 such as plastic. Especially a top surface of the plurality of dice 212 is exposed. Here, external pressure is introduced in the step to prevent the chemical compound from coating on the lower surface of the metal frame 210 portions.

With reference FIG. 12B, the metal frame 220, such as lead frame 220 is provided and the metal frame 220 is formed as a specific pattern. Especially the specific pattern is defined by the lithography including stamping process etc. A full tape 221 such as adhesive material is laminated on the backside surface of a die 222. The die 222 is located upon the metal frame 220 by the full tape 221. Here, the plurality of dice 222 are formed from the semiconductor wafer or semiconductor chip. A metal wire 224 is bonded to connect the die 222 below and normally the metal wire 224 is formed by the gold wire. Finally, molding parts of the metal frame 220 are achieved to expose parts of the metal frame 220 by a chemical compound 223 such as plastic. Especially the top surface of the plurality of dice 222 is covered by the above chemical compound. Here, external pressure is introduced in the step to prevent the chemical compound from coating on the lower surface of the metal frame 220 portions.

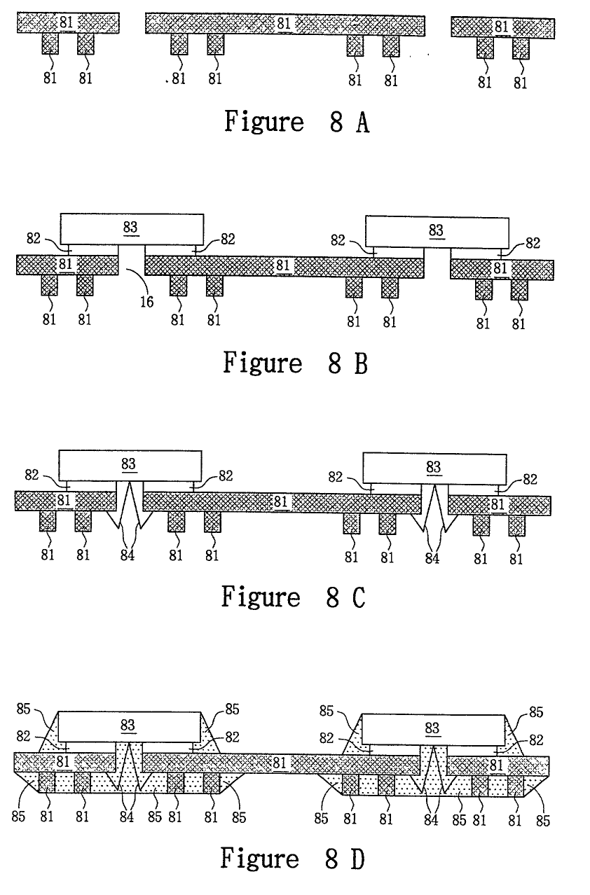

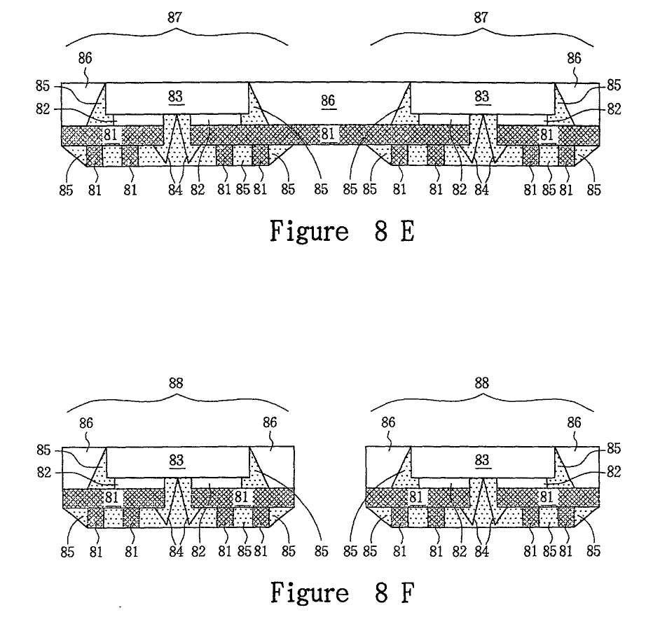

With reference FIG. 13A, the metal frame 310, such as lead frame 310 is provided and the metal frame 310 is formed as a specific pattern. Especially the specific pattern is defined by the lithography including stamping process etc. A full tape 311 such as adhesive material is laminated on the backside surface of a die 312. The die 312 is located upon the metal frame 310 by the full tape 311. Here, the plurality of dice 312 are formed from the semiconductor wafer or semiconductor chip. A metal wire 314 is bonded to connect the die 312 below and normally the metal wire 314 is formed by the gold wire. Finally, molding parts of the metal frame 310 are achieved to expose parts of the metal frame 310 by a chemical compound 313 such as plastic. Especially a top surface of the plurality of dice 312 is exposed and the formed molding shape of the chemical compound 313 is a tilt shape beside the die 312. Here, external pressure is introduced in the step to prevent the chemical compound 313 from coating on the lower surface of the metal frame 310 portions.

With reference FIG. 13B, the metal frame 320, such as lead frame 320 is provided and the metal frame 320 is formed as a specific pattern. Especially the specific pattern is defined by the lithography including stamping process etc. A full tape 321 such as adhesive material is laminated on the backside surface of a die 322. The die 322 is located upon the metal frame 320 by the full tape 321. Here, the plurality of dice 322 are formed from the semiconductor wafer or semiconductor chip. A metal wire 324 is bonded to connect the die 322 below and normally the metal wire 324 is formed by the gold wire. Finally, molding parts of the metal frame 320 are achieved to expose parts of the metal frame 320 by a chemical compound 323 such as plastic. Especially the top surface of the plurality of dice 322 is covered by the above chemical compound 323 and the formed molding shape of the chemical compound 323 is a tilt shape beside the die 312. Here, External pressure is introduced in the step to prevent the chemical compound 323 from coating on the lower surface of the metal frame 320 portions.

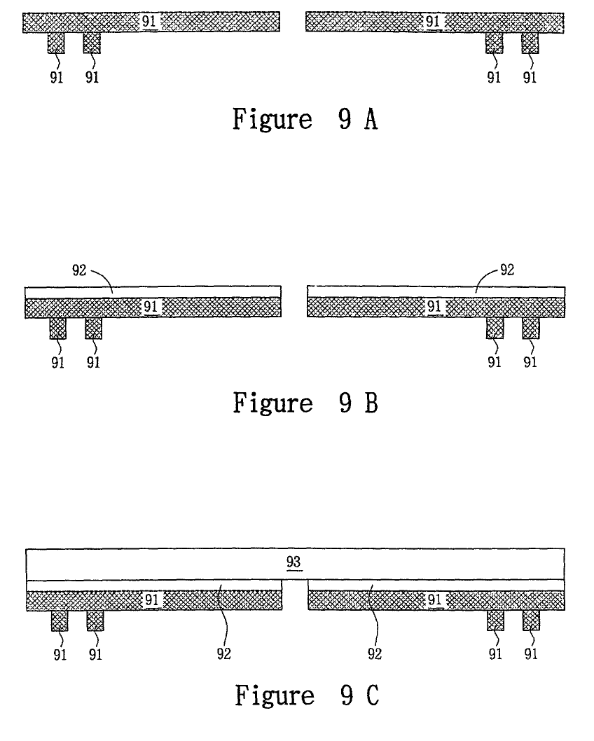

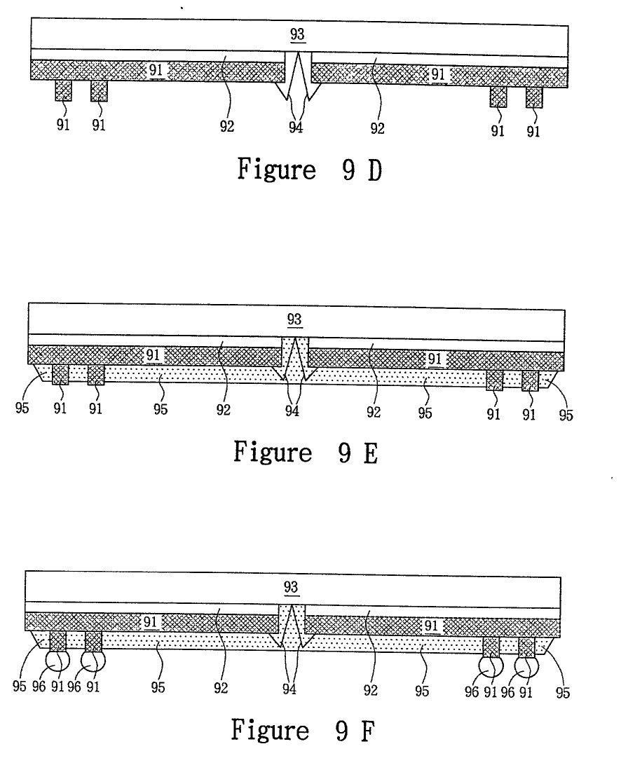

With reference FIG. 14A, the metal frame 410, such as lead frame 410 is provided and the metal frame 410 is formed as a specific pattern. Especially the specific pattern is defined by the lithography including stamping process etc. A full tape 411 such as adhesive material is laminated on the backside surface of a die 412. The die 412 is located upon the metal frame 410 by the full tape 411. Here, the plurality of dice 412 are formed from the semiconductor wafer or semiconductor chip. A metal wire 414 is bonded to connect the die 412 below and normally the metal wire 414 is formed by the gold wire. Then, molding parts of the metal frame 410 are achieved to expose parts of the metal frame 410 by a chemical compound 413 such as plastic. Finally, a plurality of metal balls 415 are placed to connect under other parts of the metal frame 410, which is the bottom portion of the metal frame 410. Especially a top surface of the plurality of dice 412 is exposed and the formed molding shape of the chemical compound 413 is a tilt shape beside the die 412. Here, External pressure is introduced in the step to prevent the chemical compound 413 from coating on the lower surface of the metal frame 410 portions.

With reference FIG. 14B, the metal frame 420, such as lead frame 420 is provided and the metal frame 420 is formed as a specific pattern. Especially the specific pattern is defined by the lithography including stamping process etc. A full tape 421 such as adhesive material is laminated on the backside surface of a die 422. The die 422 is located upon the metal frame 420 by the full tape 421. Here, the plurality of dice 422 are formed from the semiconductor wafer or semiconductor chip. A metal wire 424 is bonded to connect the die 422 below and normally the metal wire 424 is formed by the gold wire. Then, molding parts of the metal frame 420 are achieved to expose parts of the metal frame 420 by a chemical compound 423 such as plastic. Finally, a plurality of metal balls 425 are placed to connect under other parts of the metal frame 420, which is the bottom portion of the metal frame 420. Especially the top surface of the plurality of dice 422 is covered by the above chemical compound 423 and the formed molding shape of the chemical compound 423 is a tilt shape beside the die 412. Here, external pressure is introduced in the step to prevent the chemical compound 423 from coating on the lower surface of the metal frame 420 portions.

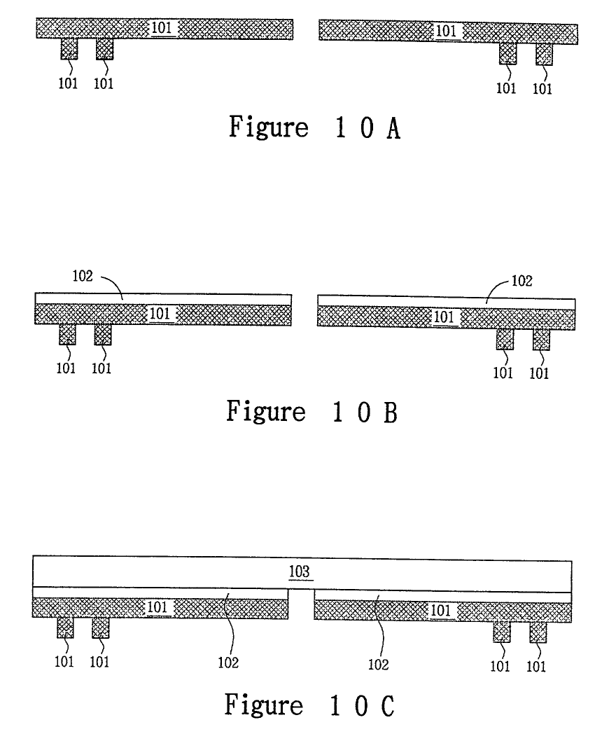

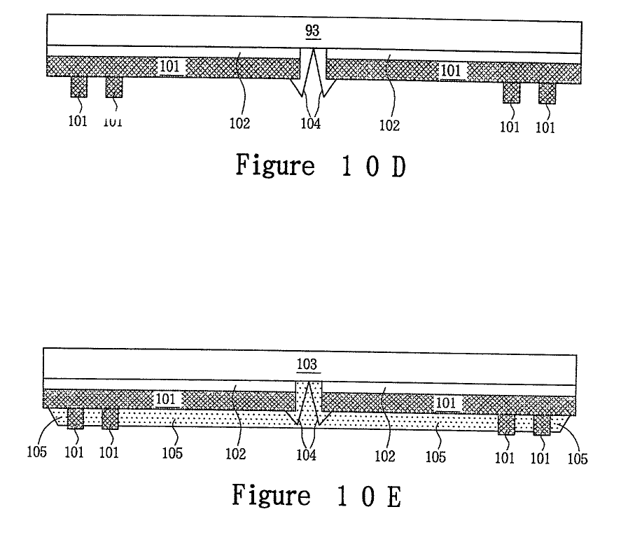

With reference FIG. 15A, the metal frame 510, such as lead frame 510 is provided and the metal frame 510 is formed as a specific pattern. Especially the specific pattern is defined by the lithography including stamping process etc. A full tape 511 such as adhesive material is laminated on the backside surface of a die 512. The die 512 is located upon the metal frame 510 by the full tape 511. Here, the plurality of dice 512 are formed from the semiconductor wafer or semiconductor chip. A metal wire 514 is bonded to connect the die 512 below and normally the metal wire 514 is formed by the gold wire. Finally, molding parts of the metal frame 510 are achieved to expose parts of the metal frame 510 by a chemical compound 513 such as plastic (As bottom housing). Especially a top surface of the plurality of dice 512 is exposed and the formed molding shape of the chemical compound 513 is around the metal frame 510 below. Here, external pressure is introduced in the step to prevent the chemical compound 513 from coating on the lower surface of the metal frame 510 portions.

With reference FIG. 15B, the metal frame 520, such as lead frame 520 is provided and the metal frame 520 is formed as a specific pattern. Especially the specific pattern is defined by the lithography including stamping process etc. A full tape 521 such as adhesive material is laminated on the backside surface of a die 522. The die 522 is located upon the metal frame 520 by the full tape 521. Here, the plurality of dice 522 are formed from the semiconductor wafer or semiconductor chip. Finally, a metal wire 523 is bonded to connect the die 522 below and normally the metal wire 523 is formed by the gold wire.

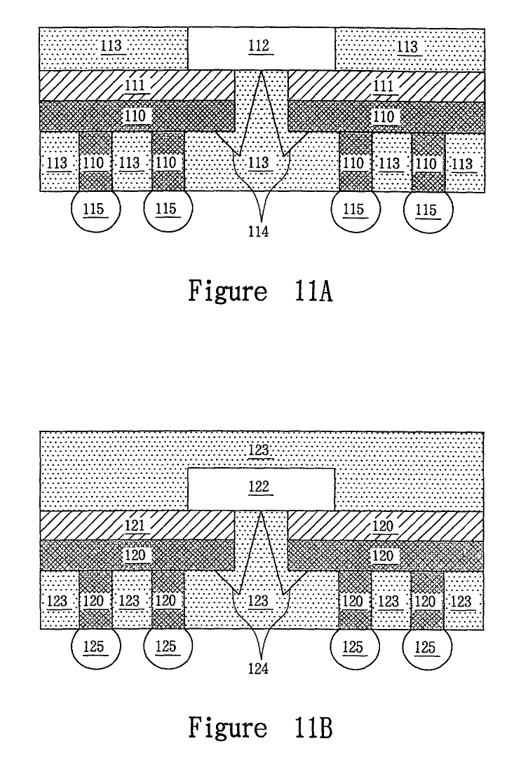

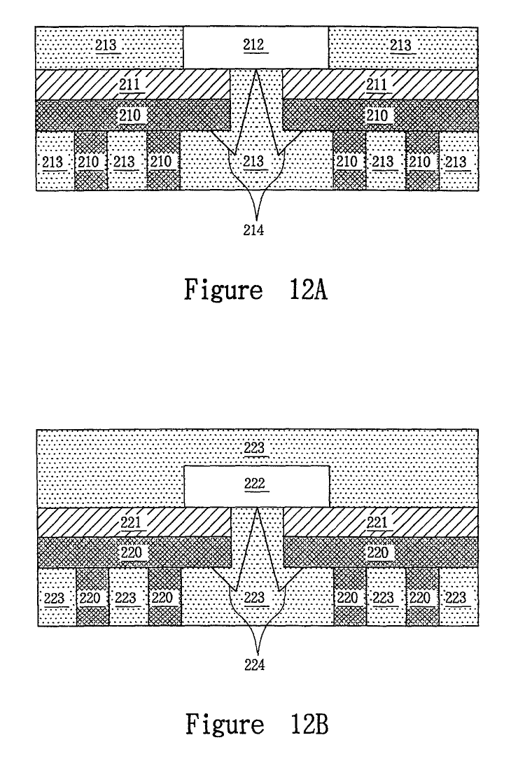

With reference FIG. 16A, the metal frame 610, such as lead frame 610 is provided and the metal frame 610 is formed as a specific pattern. Especially the specific pattern is defined by the lithography including stamping process etc. A full tape 611 such as adhesive material is laminated on the backside surface of a die 612. The die 612 is located upon the metal frame 610 by the full tape 611. Here, the plurality of dice 612 are formed from the semiconductor wafer or semiconductor chip. A metal wire 614 is bonded to connect the die 612 below and normally the metal wire 614 is formed by the gold wire. molding parts of the metal frame 610 are achieved to expose parts of the metal frame 610 by a chemical compound 613 such as plastic. Especially a top surface of the plurality of dice 612 is exposed and the formed molding shape of the chemical compound 613 is located around the metal frame 610 below. Here, external pressure is introduced in the step to prevent the chemical compound 613 from coating on the lower surface of the metal frame 610 portions. Finally, a plurality of metal balls 615 are placed to connect under other parts of the metal frame 610, which is the bottom portion of the metal frame 610.

With reference FIG. 16B, the metal frame 620, such as lead frame 620 is provided and the metal frame 620 is formed as a specific pattern. Especially the specific pattern is defined by the lithography including stamping process etc. A full tape 621 such as adhesive material is laminated on the backside surface of a die 622. The die 622 is located upon the metal frame 620 by the full tape 621. Here, the plurality of dice 622 are formed from the semiconductor wafer or semiconductor chip. A metal wire 623 is bonded to connect the die 622 below and normally the metal wire 623 is formed by the gold wire. Finally, a plurality of metal balls 624 are placed to connect under other parts of the metal frame 620, which is the bottom portion of the metal frame 620.

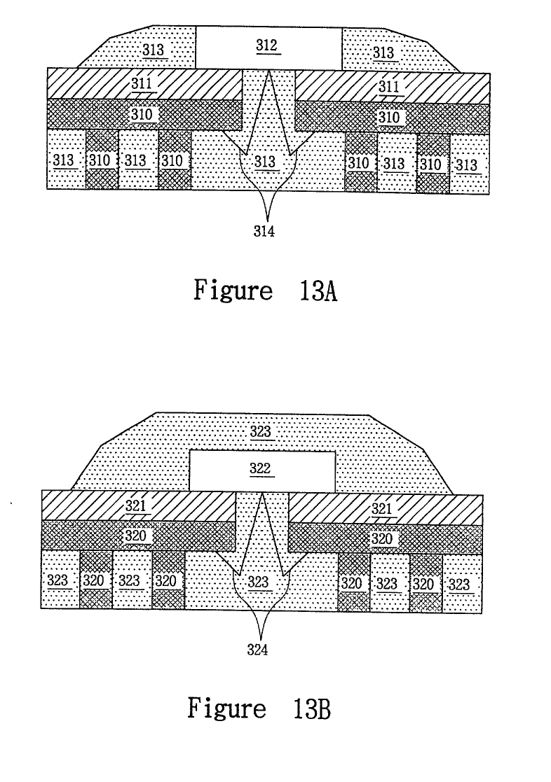

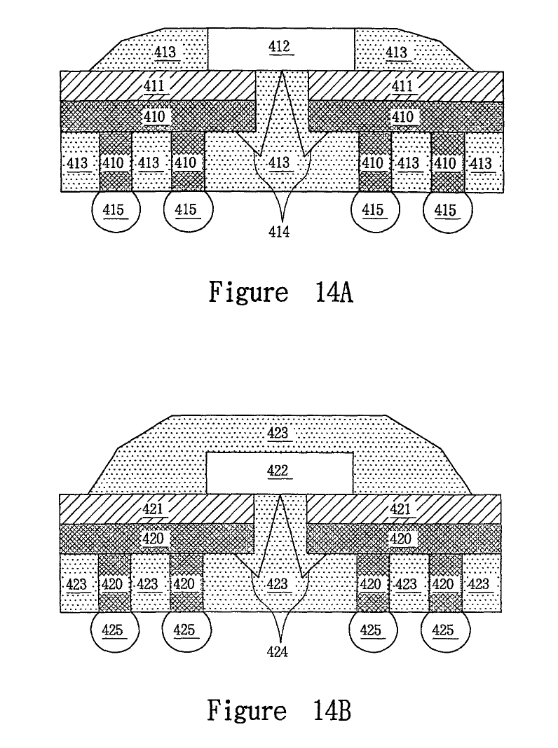

With reference FIG. 17A, the metal frame 710, such as lead frame 710 is provided and the metal frame 710 is formed as a specific pattern. Especially the specific pattern is defined by the lithography including stamping process etc. A partial tape 711 such as adhesive material is laminated on the backside surface of a die 712. The die 712 is located upon the metal frame 710 by the partial tape 711. Here, the plurality of dice 712 are formed from the semiconductor wafer or semiconductor chip. A metal wire 714 is bonded to connect the die 712 below and normally the metal wire 714 is formed by the gold wire. Finally, molding parts of the metal frame 710 are achieved to expose parts of the metal frame 710 by a chemical compound 713 such as plastic. Especially the top surface of the plurality of dice 712 is covered by the above chemical compound. Here, external pressure is introduced in the step to prevent the chemical compound from coating on the lower surface of the metal frame 710 portions.

With reference FIG. 17B, the metal frame 720, such as lead frame 720 is provided and the metal frame 720 is formed as a specific pattern. Especially the specific pattern is defined by the lithography including stamping process etc. A partial tape 721 such as adhesive material is laminated on the backside surface of a die 722. The die 722 is located upon the metal frame 720 by the full tape 721. Here, the plurality of dice 722 are formed from the semiconductor wafer or semiconductor chip. A metal wire 724 is bonded to connect the die 722 below and normally the metal wire 724 is formed by the gold wire. Finally, molding parts of the metal frame 720 are achieved to expose parts of the metal frame 720 by a chemical compound 723 such as plastic. Especially a top surface of the plurality of dice 722 is exposed. Here, external pressure is introduced in the step to prevent the chemical compound from coating on the lower surface of the metal frame 720 portions.

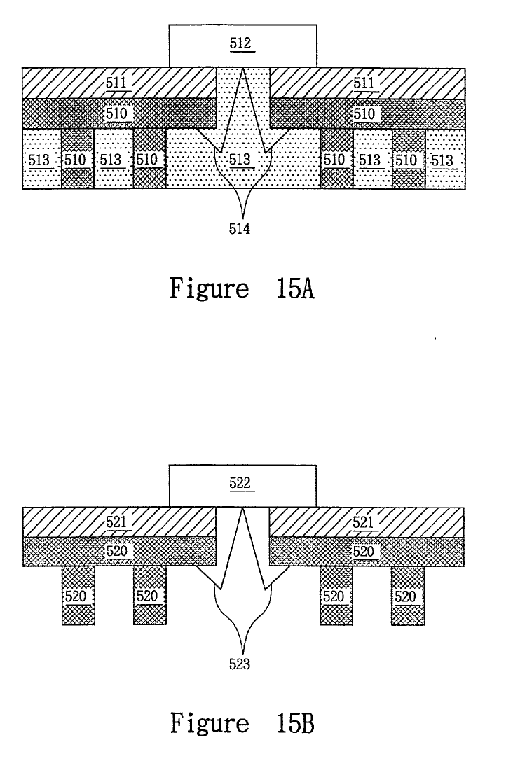

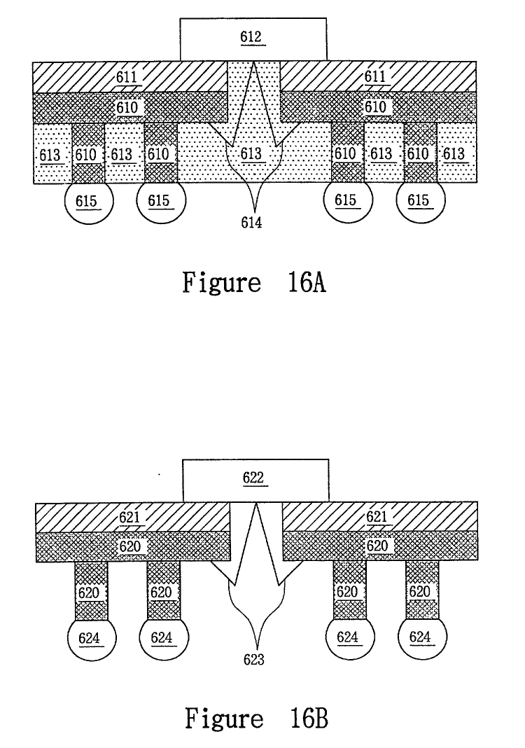

With reference FIG. 18A, the metal frame 810, such as lead frame 810 is provided and the metal frame 810 is formed as a specific pattern. Especially the specific pattern is defined by the lithography including stamping process etc. A partial tape 811 such as adhesive material is laminated on the backside surface of a die 812. The die 812 is located upon the metal frame 810 by the partial tape 811. Here, the plurality of dice 812 are formed from the semiconductor wafer or semiconductor chip. A metal wire 814 is bonded to connect the die 812 below and normally the metal wire 814 is formed by the gold wire. Finally, molding parts of the metal frame 810 are achieved to expose parts of the metal frame 810 by a chemical compound 813 such as plastic. Especially the top surface of the plurality of dice 812 is covered by the above chemical compound. Here, external pressure is introduced in the step to prevent the chemical compound from coating on the lower surface of the metal frame 810 portions. Finally, a plurality of metal balls 815 are placed to connect under other parts of the metal frame 810, which is the bottom portion of the metal frame 810.

With reference FIG. 18B, the metal frame 820, such as lead frame 820 is provided and the metal frame 820 is formed as a specific pattern. Especially the specific pattern is defined by the lithography including stamping process etc. A partial tape 821 such as adhesive material is laminated on the backside surface of a die 822. The die 822 is located upon the metal frame 820 by the full tape 821. Here, the plurality of dice 822 are formed from the semiconductor wafer or semiconductor chip. A metal wire 824 is bonded to connect the die 822 below and normally the metal wire 824 is formed by the gold wire. Finally, molding parts of the metal frame 820 are achieved to expose parts of the metal frame 820 by a chemical compound 823 such as plastic. Especially a top surface of the plurality of dice 822 is exposed. Here, external pressure is introduced in the step to prevent the chemical compound from coating on the lower surface of the metal frame 820 portions. Finally, a plurality of metal balls 825 are placed to connect under other parts of the metal frame 820, which is the bottom portion of the metal frame 820.

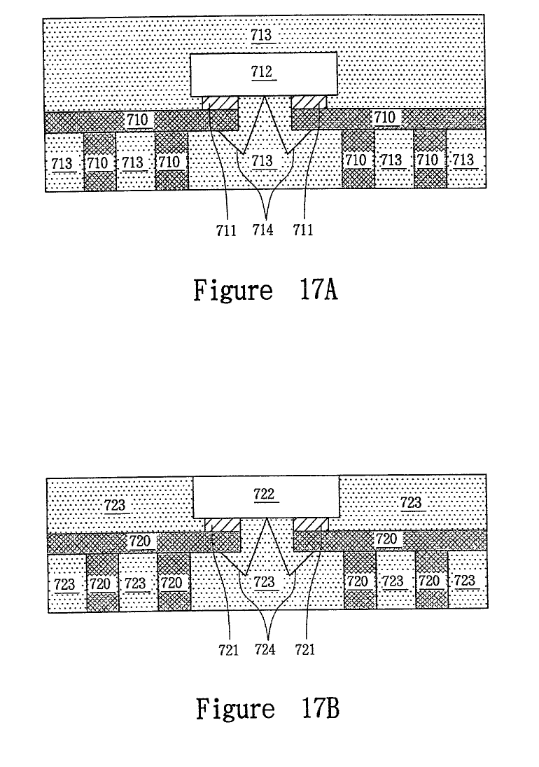

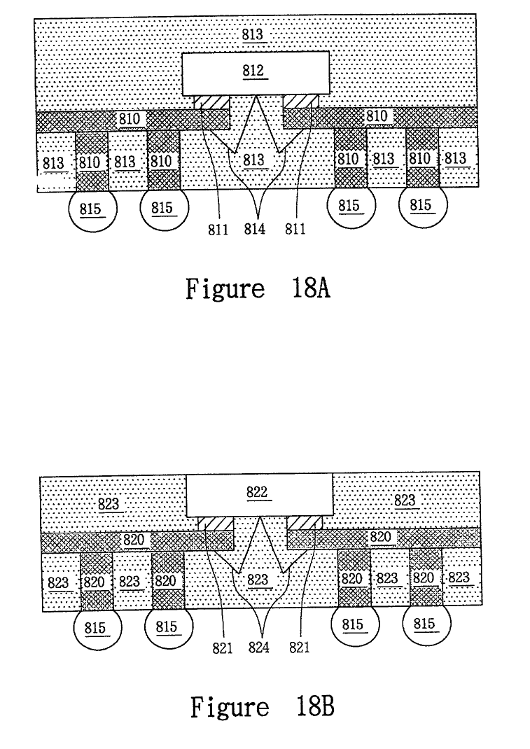

With reference FIG. 19A, the metal frame 910, such as lead frame 910 is provided and the metal frame 910 is formed as a specific pattern. Especially the specific pattern is defined by the lithography including stamping process etc. A partial tape 911 such as adhesive material is laminated on the backside surface of a die 912. The die 912 is located upon the metal frame 910 by the partial tape 911. Here, the plurality of dice 912 are formed from the semiconductor wafer or semiconductor chip. A metal wire 914 is bonded to connect the die 912 below and normally the metal wire 914 is formed by the gold wire. Finally, molding parts of the metal frame 910 are achieved to expose parts of the metal frame 910 by a chemical compound 913 such as plastic. Especially a top surface of the plurality of dice 912 is exposed and the formed molding shape of the chemical compound 913 is around the metal frame 910 below. Here, external pressure is introduced in the step to prevent the chemical compound 913 from coating on the lower surface of the metal frame 910 portions.

With reference FIG. 19B, the metal frame 920, such as lead frame 920 is provided and the metal frame 920 is formed as a specific pattern. Especially the specific pattern is defined by the lithography including stamping process etc. A partial tape 921 such as adhesive material is laminated on the backside surface of a die 922. The die 922 is located upon the metal frame 920 by the partial tape 921. Here, the plurality of dice 922 are formed from the semiconductor wafer or semiconductor chip. A metal wire 923 is bonded to connect the die 922 below and normally the metal wire 923 is formed by the gold wire. Finally, the metal wire 923 is packed by a chemical compound 924 such as plastic. Especially the molding shape of the chemical compound 924 is around the metal frame 920 below and as a triangle shape (As tilt bottom housing).

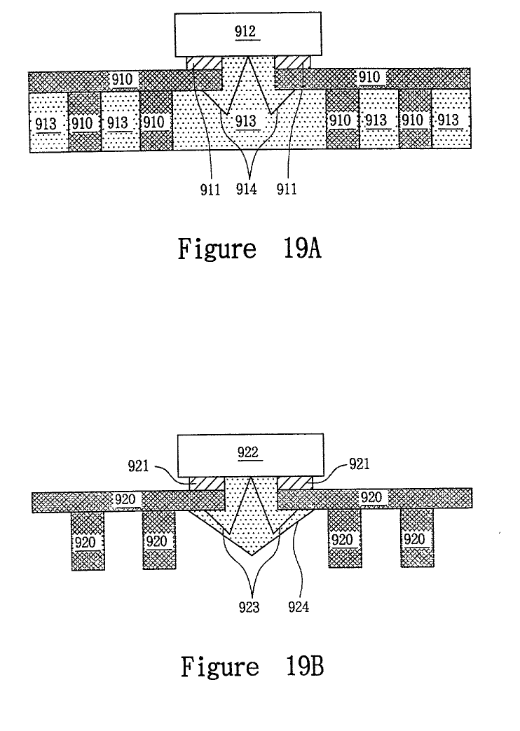

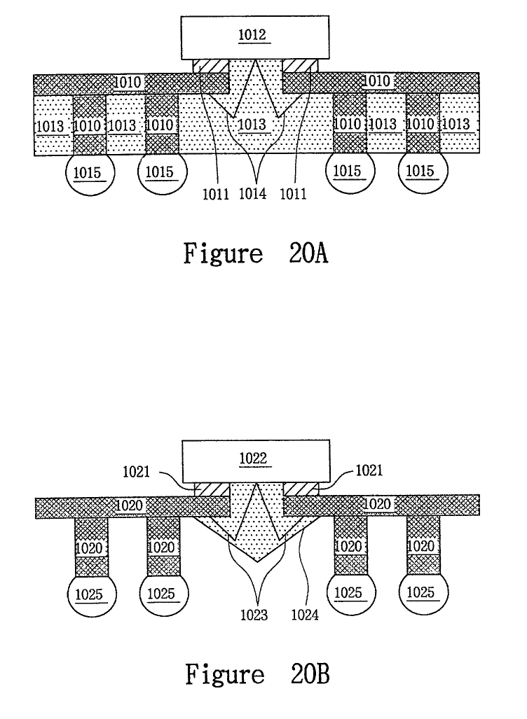

With reference FIG. 20A, the metal frame 1010, such as lead frame 1010 is provided and the metal frame 1010 is formed as a specific pattern. Especially the specific pattern is defined by the lithography including stamping process etc. A partial tape 1011 such as adhesive material is laminated on the backside surface of a die 1012. The die 1012 is located upon the metal frame 1010 by the partial tape 1011. Here, the plurality of dice 1012 are formed from the semiconductor wafer or semiconductor chip. A metal wire 1014 is bonded to connect the die 1012 below and normally the metal wire 1014 is formed by the gold wire. The molding parts of the metal frame 1010 are achieved to expose parts of the metal frame 1010 by a chemical compound 1013 such as plastic. Especially a top surface of the plurality of dice 1012 is exposed and the formed molding shape of the chemical compound 1013 is around the metal frame 1010 below. Finally, a plurality of metal balls 1015 are placed to connect under other parts of the metal frame 1010, which is the bottom portion of the metal frame 1010. Here, external pressure is introduced in the step to prevent the chemical compound 1013 from coating on the lower surface of the metal frame 1010 portions.

With reference FIG. 20B, the metal frame 1020, such as lead frame 1020 is provided and the metal frame 1020 is formed as a specific pattern. Especially the specific pattern is defined by the lithography including stamping process etc. A partial tape 1021 such as adhesive material is laminated on the backside surface of a die 1022. The die 1022 is located upon the metal frame 1020 by the partial tape 1021. Here, the plurality of dice 1022 are formed from the semiconductor wafer or semiconductor chip. A metal wire 1024 is bonded to connect the die 1022 below and normally the metal wire 1024 is formed by the gold wire. The metal wire 1023 is packed by a chemical compound 1024 such as plastic. Especially the molding shape of the chemical compound 1024 is around the metal frame 1020 below and as a triangle shape (as tilt bottom housing). Finally, a plurality of metal balls 1025 are placed to connect under other parts of the metal frame 1020, which is the bottom portion of the metal frame 1020.

According to the above statement, as FIG. 1G, FIG. 5G, FIG. 6G, FIG. 11A, FIG. 16A and FIG. 14A, an apparatus for packing a semiconductor die will comprise the followings:

A semiconductor die is sticked thereon a metal frame by a full tape which is an adhesive material, an uncovered housing is formed around the semiconductor die and around a part of the metal frame, wherein the metal frame having a metal wire connected the die below, a plurality of metal balls being connected under other parts of the metal frame.

According to the above statement, as FIG. 2G, FIG. 11B, FIG. 14B, and FIG. 18A, an apparatus for packing a semiconductor die will comprise the followings:

A semiconductor die is sticked thereon a metal frame by a full tape which is an adhesive material, a covered housing is formed around the semiconductor die and around a part of the metal frame, wherein the metal frame having a metal wire connected the die below, a plurality of metal balls being connected under other parts of the metal frame.

According to the above statement, as FIG. 3F, FIG. 4F, FIG. 12B and FIG. 13B, an apparatus for packing a semiconductor die will comprise the followings:

A semiconductor die is sticked thereon a metal frame by a full tape which is an adhesive material, a covered housing is formed around the semiconductor die and around a part of the metal frame, wherein the metal frame having a metal wire connected the die below.

According to the above statemenet, as FIG. 7F and FIG. 8F, FIG. 12A and FIG. 13A, an apparatus for packing a semiconductor die will comprise the followings:

A semiconductor die is sticked thereon a metal frame by a full tape which is an adhesive material, an uncovered housing is formed around the semiconductor die and around a part of the metal frame, wherein the metal frame having a metal wire connected the die below.

According to the above statemenet, as FIG. 9F, an apparatus for packing a semiconductor die will comprise the followings:

A semiconductor die is sticked thereon a metal frame by a full tape which is an adhesive material, a bottom housing is formed around a part of the metal frame, wherein the metal frame having a metal wire connected the die below, a plurality of metal balls being connected under other parts of the metal frame.

According to the above statement, as FIG. 10E, FIG. 15A an apparatus for packing a semiconductor die will comprise the followings:

A semiconductor die is sticked thereon a metal frame by a full tape which is an adhesive material, a bottom housing is formed around the semiconductor die and around a part of the metal frame, wherein the metal frame having a metal wire connected the die below.

According to the above statement, as FIG. 15B, an apparatus for packing a semiconductor die will comprise the followings:

A semiconductor die is sticked thereon a metal frame by a full tape which is an adhesive material, wherein the metal frame having a metal wire connected the die below.

According to the above statement, as FIG. 16B, an apparatus for packing a semiconductor die will comprise the followings:

A semiconductor die is sticked thereon a metal frame by a full tape which is an adhesive material, wherein the metal frame having a metal wire connected the die below, a plurality of metal balls are connected under other parts of the metal frame.

According to the above statement, as FIG. 17A, an apparatus for packing a semiconductor die will comprise the followings:

A semiconductor die is sticked thereon a metal frame by a half tape which is an adhesive material, a covered housing is formed around the semiconductor die and around a part of the metal frame, wherein the metal frame having a metal wire connected the die below.

According to the above statement, as FIG. 17B, an apparatus for packing a semiconductor die will comprise the followings:

A semiconductor die is sticked thereon a metal frame by a half tape which is an adhesive material, an uncovered housing is formed around the semiconductor die and around a part of the metal frame, wherein the metal frame having a metal wire connected the die below.

According to the above statement, as FIG. 18A, an apparatus for packing a semiconductor die will comprise the followings:

A semiconductor die is sticked thereon a metal frame by a half tape which is an adhesive material, a covered housing is formed around the semiconductor die and around a part of the metal frame, wherein the metal frame having a metal wire connected the die below, a plurality of metal balls being connected under other parts of the metal frame.

According to the above statement, as FIG. 18B, an apparatus for packing a semiconductor die will comprise the followings:

A semiconductor die is sticked thereon a metal frame by a half tape which is an adhesive material, an uncovered housing is formed around the semiconductor die and around a part of the metal frame, wherein the metal frame having a metal wire connected the die below, a plurality of metal balls are connected under other parts of the metal frame.

According to the above statement, as FIG. 19A, an apparatus for packing a semiconductor die will comprise the followings:

A semiconductor die is sticked thereon a metal frame by a half tape which is an adhesive material, wherein the metal frame having a metal wire connected the die below, a bottom housing is formed around the semiconductor die, the metal wire and around a part of the metal frame.

According to the above statement, as FIG. 19B, an apparatus for packing a semiconductor die will comprise the followings:

A semiconductor die is sticked thereon a metal frame by a half tape which is an adhesive material, wherein the metal frame having a metal wire connected the die below, a tilt bottom housing is formed around the semiconductor die, the metal wire and around a part of the metal frame.

According to the above statement, as FIG. 20A, an apparatus for packing a semiconductor die will comprise the followings:

A semiconductor die is sticked thereon a metal frame by a half tape which is an adhesive material, wherein the metal frame having a metal wire connected the die below, a bottom housing is formed around the semiconductor die, the metal wire and around a part of the metal frame, a plurality of metal balls are connected under other parts of the metal frame.

According to the above statement, as FIG. 20B, an apparatus for packing a semiconductor die will comprise the followings:

A semiconductor die is sticked thereon a metal frame by a half tape which is an adhesive material, wherein the metal frame having a metal wire connected the die below, a tilt bottom housing is formed around the semiconductor die, the metal wire and around a part of the metal frame, a plurality of metal balls are connected under other parts of the metal frame.

Therefore, according to the above statement, the advantages for the invention can be describes as the followings:

1. The high frequency requirement is easily achieved.

2. The package cost can be exactly decreased.

The cycle time will be shorten.

Although specific embodiments have been illustrated and described, it will be obvious to those skilled in the art that various modifications may be made without departing from what is intended to be limited solely by the appended claims.

What is claimed is:

1. An apparatus for packing a semiconductor die, comprising:
a semiconductor die is sticked thereon a metal frame by a full tape which is an adhesive material, an uncovered housing is formed around the semiconductor die and around a part of the metal frame, wherein the metal frame having a metal wire connected the die below, a plurality of metal balls being connected under other parts of the metal frame.

2. An apparatus for packing a semiconductor die, comprising:
a semiconductor die is sticked thereon a metal frame by a full tape which is an adhesive material, a covered housing is formed around the semiconductor die and around a part of the metal frame, wherein the metal frame having a metal wire connected the die below, a plurality of metal balls being connected under other parts of the metal frame.

3. An apparatus for packing a semiconductor die, comprising:
a semiconductor die is sticked thereon a metal frame by a full tape which is an adhesive material, a covered housing is formed around the semiconductor die and around a part of the metal frame, wherein the metal frame having a metal wire connected the die below.

4. An apparatus for packing a semiconductor die, comprising:
a semiconductor die is sticked thereon a metal frame by a full tape which is an adhesive material, an uncovered housing is formed around the semiconductor die and around a part of the metal frame, wherein the metal frame having a metal wire connected the die below.

5. An apparatus for packing a semiconductor die, comprising:
a semiconductor die is sticked thereon a metal frame by a full tape which is an adhesive material, a bottom housing is formed around a part of the metal frame, wherein the metal frame having a metal wire connected the die below, a plurality of metal balls being connected under other parts of the metal frame.

6. An apparatus for packing a semiconductor die, comprising:
a semiconductor die is sticked thereon a metal frame by a full tape which is an adhesive material, a bottom housing is formed around the semiconductor die and around a part of the metal frame, wherein the metal frame having a metal wire connected the die below.

7. An apparatus for packing a semiconductor die, comprising:
a semiconductor die is sticked thereon a metal frame by a full tape which is an adhesive material, wherein the metal frame having a metal wire connected the die below.

8. An apparatus for packing a semiconductor die, comprising:
a semiconductor die is sticked thereon a metal frame by a full tape which is an adhesive material, wherein the metal frame having a metal wire connected the die below, a plurality of metal balls being connected under other parts of the metal frame.

9. An apparatus for packing a semiconductor die, comprising:
a semiconductor die is sticked thereon a metal frame by a half tape which is an adhesive material, a covered housing is formed around the semiconductor die and around a part of the metal frame, wherein the metal frame having a metal wire connected the die below.

10. An apparatus for packing a semiconductor die, comprising:
a semiconductor die is sticked thereon a metal frame by a half tape which is an adhesive material, an uncovered housing is formed around the semiconductor die and around a part of the metal frame, wherein the metal frame having a metal wire connected the die below.

11. An apparatus for packing a semiconductor die, comprising:
a semiconductor die is sticked thereon a metal frame by a half tape which is an adhesive material, an covered housing is formed around the semiconductor die and around a part of the metal frame, wherein the metal frame having a metal wire connected the die below, a plurality of metal balls being connected under other parts of the metal frame.

12. An apparatus for packing a semiconductor die, comprising:
a semiconductor die is sticked thereon a metal frame by a half tape which is an adhesive material, an uncovered housing is formed around the semiconductor die and around a part of the metal frame, wherein the metal frame having a metal wire connected the die below, a plurality of metal balls are connected under other parts of the metal frame.

13. An apparatus for packing a semiconductor die, comprising:
a semiconductor die is sticked thereon a metal frame by a half tape which is an adhesive material, wherein the metal frame having a metal wire connected the die below, a bottom housing is formed around the semiconductor die, the metal wire and around a part of the metal frame.

14. An apparatus for packing a semiconductor die, comprising:
a semiconductor die is sticked thereon a metal frame by a half tape which is an adhesive material, wherein the metal frame having a metal wire connected the die below, a tilt bottom housing is formed around the semiconductor die, the metal wire and around a part of the metal frame.

15. An apparatus for packing a semiconductor die, comprising:
a semiconductor die is sticked thereon a metal frame by a half tape which is an adhesive material, a bottom housing is formed around the semiconductor die, a metal wire and around a part of the metal frame, a plurality of metal balls are connected under other parts of the metal frame.

16. An apparatus for packing a semiconductor die, comprising:
a semiconductor die is sticked thereon a metal frame by a half tape which is an adhesive material, wherein the metal frame having a metal wire connected the die below, a tilt bottom housing is formed around the semiconductor die, the metal wire and around a part of the metal frame, a plurality of metal balls are connected under other parts of the metal frame.
